(19) United States
(12) Patent Application Publication
(10) Pub. No.: US 2026/0033202 A1
(43) Pub. Date: Jan. 29, 2026

(54) PIXEL ARRANGEMENT STRUCTURE AND DISPLAY PANEL

(71) Applicant: HKC CORPORATION LIMITED, SHENZHEN (CN)

(72) Inventors: Zhiwei YE, SHENZHEN (CN); Chen CHEN, SHENZHEN (CN); Xiufeng ZHOU, SHENZHEN (CN); Lidan YE, SHENZHEN (CN)

(73) Assignee: HKC CORPORATION LIMITED, SHENZHEN (CN)

(21) Appl. No.: 19/271,832

(22) Filed: Jul. 17, 2025

(30) Foreign Application Priority Data
Jul. 29, 2024 (CN) 202411029788.9

(51) Int. Cl. H10K 59/35; H10K 59/122

(52) U.S. Cl. CPC H10K 59/353; H10K 59/122

(57) ABSTRACT

A pixel arrangement structure and a display panel are provided. The pixel arrangement structure includes multiple pixel units. Each of the pixel plurality of pixel units includes a first sub-pixel and a second sub-pixel of different sizes, and two third sub-pixels aligned with the first sub-pixel and the second sub-pixel. In each of the pixel plurality of pixel units, the first sub-pixel and the second sub-pixel are diagonally arranged, one of the two third sub-pixels is aligned with the first sub-pixel in a first direction and aligned with the second sub-pixel in a second direction, another of the two third sub-pixels is aligned with the second sub-pixel in the first direction and aligned with the first sub-pixel in the second direction, and the first direction and the second direction are arranged at an angle.

### CROSS REFERENCE TO RELATED APPLICATIONS

The present disclosure claims foreign priority to Chinese Patent Application No. 202411029788.9, filed on Jul. 29, 2024, the contents of which are hereby incorporated by reference in its entirety.

### TECHNICAL FIELD

The present disclosure relates to the field of display technologies, in particular to a pixel arrangement structure and a display panel.

### BACKGROUND

An organic light-emitting diode (OLED) display device has advantages such as low energy consumption, low production cost, spontaneous light, wide viewing angle, fast response and the like compared to a traditional liquid crystal display device. The OLED display device is currently a popular field in the display research and is increasingly used in mobile phones and tablets.

Currently, in a manufacturing process of the OLED display device, a fine metal mask (FMM) is used, an organic material is deposited through a vacuum evaporation deposition process, and the area and shape of the organic material is controlled through openings in the FMM to form an organic electroluminescent structure. Due to the limitations of the minimum opening size and minimum distance between the openings in the FMM, an increase in the number of openings in the FMM results in a loss of the aperture ratio of active area (AA) of the pixel structure. Therefore, it is difficult to achieve both high resolution and high aperture ratio in the display device, that is, high aperture ratio is difficult to be ensured when the display device has high resolution, otherwise, defects such as color mixing is easy to occur.

Additionally, when the light-emitting centers of three sub-pixels in a pixel unit are not aligned with the center of the pixel unit, jagged edges or colored edges may occur when straight lines are displayed.

### SUMMARY

A pixel arrangement structure is provided. The pixel arrangement structure includes multiple pixel units. Each of the pixel plurality of pixel units includes a first sub-pixel and a second sub-pixel of different sizes, and two third sub-pixels aligned with the first sub-pixel and the second sub-pixel. In each of the pixel plurality of pixel units, the first sub-pixel and the second sub-pixel are diagonally arranged, one of the two third sub-pixels is aligned with the first sub-pixel in a first direction and aligned with the second sub-pixel in a second direction, another of the two third sub-pixels is aligned with the second sub-pixel in the first direction and aligned with the first sub-pixel in the second direction, and the first direction and the second direction are arranged at an angle.

A display panel is provided. The display panel includes any one of the above pixel arrangement structures. Sub-pixels of different colors are separated by a conductor barrier structure, and at least two sub-pixels of the same color share a part of the conductor barrier structure.

A display panel is provided. The pixel arrangement structure includes multiple pixel units. Each of the pixel plurality of pixel units includes a first sub-pixel and a second sub-pixel of different sizes, and two third sub-pixels aligned with the first sub-pixel and the second sub-pixel. In each of the pixel plurality of pixel units, the first sub-pixel and the second sub-pixel are diagonally arranged. Each of the pixel plurality of pixel units is in a shape of a parallelogram.

### BRIEF DESCRIPTION OF THE DRAWINGS

In order to make the technical solutions described in embodiments of the present disclosure more clearly, the drawings used for description of some embodiments are described. Apparently, the drawings in the following description only illustrate some embodiments of the present disclosure. For those skilled in the art, other drawings may be acquired according to the drawings without any creative work.

FIG. 1 is a structural schematic view of an embodiment a pixel arrangement structure according to the present disclosure.

FIG. 2 is a structural schematic view of a first embodiment of a pixel unit according to the present disclosure.

FIG. 3 is a structural schematic view of a second embodiment of a pixel unit according to the present disclosure.

FIG. 4 is a structural schematic view of a third embodiment of a pixel unit according to the present disclosure.

FIG. 5 is a structural schematic view of a fourth embodiment of a pixel unit according to the present disclosure.

FIG. 6 is a cross-sectional structural schematic view of a first embodiment of a pixel arrangement structure according to the present disclosure.

FIG. 7 is a cross-sectional structural schematic view of a second embodiment of a pixel arrangement structure according to the present disclosure.

FIG. 8 is a cross-sectional structural schematic view of a third embodiment of a pixel arrangement structure according to the present disclosure.

FIG. 9 is a structural schematic view of a first embodiment of a display panel according to the present disclosure.

FIG. 10 is a structural schematic view of a second embodiment of a display panel according to the present disclosure.

FIG. 11 is a cross-sectional structural schematic view of a first specific embodiment of a display panel according to the present disclosure.

FIG. 12 is a structural schematic view of a third embodiment of a display panel according to the present disclosure.

FIG. 13 is a cross-sectional structural schematic view of a second specific embodiment of a display panel according to the present disclosure.

### DETAILED DESCRIPTIONS

The following describes the technical solutions of some embodiments of the present disclosure in detail with reference to the drawings.

In the following description, details such as system structures, interfaces, and technologies are provided for description only and not for limitation, to facilitate a thorough understanding of the present disclosure.

The technical solutions in embodiments of the present disclosure are clearly and completely described in conjunction with the drawings in the embodiments of the present disclosure. It is obvious that the described embodiments are only some embodiments of the present disclosure, and not all embodiments. All other embodiments acquired by those skilled in the art based on the embodiments in the present disclosure without the creative work are all within the scope of the present disclosure.

In the present disclosure, the terms “first,” “second,” and “third” are used for descriptive purposes only and should not be understood as indicating or implying relative importance or implicitly specifying the quantity of the indicated technical features. Thus, features defined by “first,” “second,” or “third” may explicitly or implicitly include at least one such feature. In the description of the present disclosure, “plurality” or “multiple” means at least two, such as two, three, etc., unless otherwise explicitly defined. Directional terms (e.g., upper, down, left, right, front, rear, etc.) in the embodiments of the present disclosure are only used to explain the relative positional relationships or movements of components in a specific posture (as shown in the drawings). If the specific posture changes, the directional terms will change accordingly. In addition, the terms “include” and “have” and any variations thereof are intended to cover non-exclusive inclusion. For example, a process, a method, a system, a product, or a device that includes a series of operations or units is not limited to the listed operations or units, but optionally also includes operations or units not listed, or optionally includes other operations or units inherent to the process, the method, the product, or the device.

“Embodiment” mentioned in the present disclosure means that specific features, structures, or characteristics described in conjunction with embodiments may be included in at least one embodiment of the present disclosure. Some embodiments including a phrase appearing in various positions in the specification does not necessarily refer to the same embodiment, and are not independents or alternative embodiment that are mutually exclusive with other embodiments. Those skilled in the art explicitly and implicitly understand that the embodiments described in the present disclosure can be combined with other embodiments.

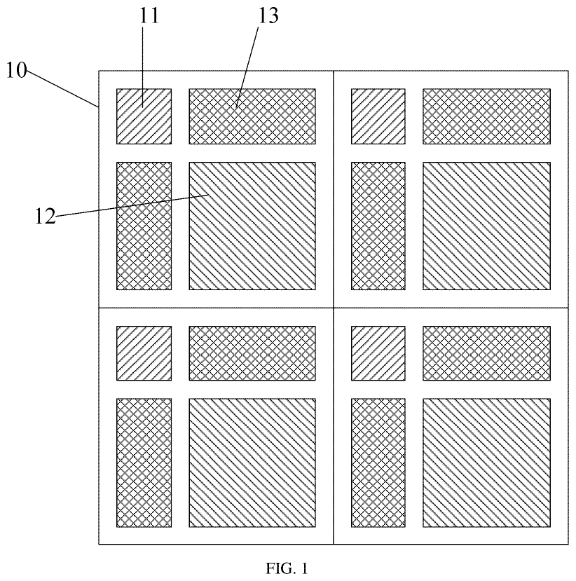

Please refer to FIG. 1, FIG. 1 is a structural schematic view of an embodiment a pixel arrangement structure according to the present disclosure. As shown in FIG. 1, the pixel arrangement structure may include multiple pixel units 10. Each pixel unit 10 may include a first sub-pixel 11 and a second sub-pixel 12 of different sizes, and two third sub-pixels 13 aligned with the first sub-pixel 11 and the second sub-pixel 12 to form the pixel unit 10 with all four aligned sides, to form the pixel unit 10 with all four aligned sides, thereby solving the problem of colored edge caused by three misaligned sub-pixels. In some embodiments, as shown in FIG. 1, the first sub-pixel 11 and the second sub-pixel 12 may be diagonally arranged at two corner positions of the parallelogram-shaped pixel unit 10, and the two third sub-pixels 13 are diagonally arranged at the other two corner positions of the parallelogram-shaped pixel unit 10.

The first sub-pixel 11, the second sub-pixel 12, and the third sub-pixel 13 may be one of a red sub-pixel R, a green sub-pixel G, and a blue sub-pixel B, and the first sub-pixel 11, the second sub-pixel 12, and the third sub-pixel 13 may have different colors. In some embodiments, the first sub-pixel 11 is a red sub-pixel, the second sub-pixel 12 is a blue sub-pixel, and the third sub-pixel 13 is a green sub-pixel. In some embodiments, the first sub-pixel 11 is a red sub-pixel, the second sub-pixel 12 is a green sub-pixel, and the third sub-pixel 13 is a blue sub-pixel. In some embodiments, the first sub-pixel 11 is a green sub-pixel, the second sub-pixel 12 is a blue sub-pixel, and the third sub-pixel 13 is a red sub-pixel, which are not limited.

In this embodiment, by splitting one of the sub-pixels forming the pixel unit 10 into two sub-pixels of the same color and aligning the split sub-pixels with the other two sub-pixels of different colors, the pixel unit 10 with four aligned sides is formed. This avoids forming an irregular pixel unit, facilitates the formation of a pixel arrangement structure arranged in an array, and reduces the problem that the colored edge is displayed.

In some embodiments, one of the third sub-pixels 13 in the same pixel unit 10 may be arranged along a first direction, and another third sub-pixel 13 in the same pixel unit 10 may be arranged along a second direction. In this embodiment, the first direction and the second direction may be arranged at 90 degrees angle. In other embodiments, the first direction and the second direction may be arranged at an acute or obtuse angle, which is not limited.

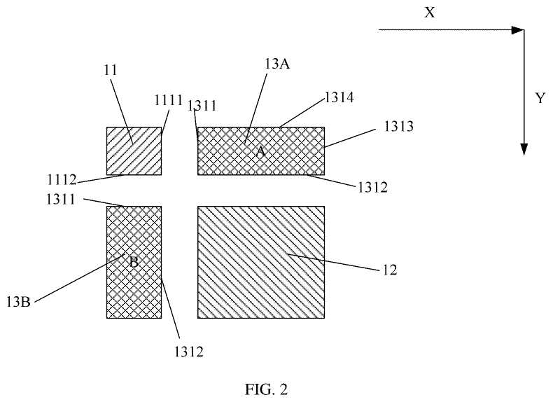

In this embodiment, the third sub-pixel 13 arranged along the first direction may be aligned with the first sub-pixel 11 in the first direction and aligned with the second sub-pixel 12 in the second direction. The third sub-pixel 13 arranged along the second direction may be aligned with the first sub-pixel 11 in the second direction and aligned with the second sub-pixel 12 in the first direction. In some embodiments, please refer to FIG. 2, FIG. 2 is a structural schematic view of a first embodiment of a pixel unit according to the present disclosure. As shown in FIG. 2, the first direction X may be the row direction, and the second direction Y may be the column direction.

In other embodiments, the angle between the first direction X and the second direction Y may be less than 90 degrees, which is not limited here. The third sub-pixel 13A arranged along the first direction X is aligned with the first sub-pixel 11 in the first direction X and aligned with the second sub-pixel 12 in the second direction Y. The third sub-pixel 13B arranged along the second direction Y is aligned with the second sub-pixel 12 in the first direction X and aligned with the first sub-pixel 11 in the second direction Y. The third sub-pixel 13A arranged along the first direction X and the third sub-pixel 13B arranged along the second direction Y have the same color, which may both be red sub-pixels, green sub-pixels, or blue sub-pixels.

It should be noted that the third sub-pixel 13 may include the first third sub-pixel 13A and the second third sub-pixel 13B. The arrangement direction of the third sub-pixel 13 refers to the direction of the long side of the third sub-pixel 13. In some embodiments, the third sub-pixel 13A arranged along the first direction X may refer to the third sub-pixel 13 with the long side arranged along the first direction X. The third sub-pixel 13B arranged along the second direction Y may refer to the third sub-pixel 13 with the long side arranged along the second direction Y.

In some embodiments, each third sub-pixel 13 at least includes a first side 1311 and a second side 1312 that are arranged adjacent to each other, and the first side 1311 and the second side 1312 have different lengths. The first sides 1311 of the two third sub-pixels 13 are adjacent to and aligned with the first sub-pixel 11, and the lengths of the first sides 1311 are equal to the lengths of the adjacent sides of the first sub-pixel 11. The second sides 1312 of the two third sub-pixels 13 are adjacent to and aligned with the second sub-pixel 12, and the lengths of the second sides 1312 are equal to the lengths of the adjacent sides of the second sub-pixel 12. In some embodiments, the first sides 1311 of the two third sub-pixels 13 may be respectively aligned with the adjacent sides of the first sub-pixel 11.

In some embodiments, the first sub-pixel 11 may include a first side 1111 and a second side 1112. The first side 1311 of the third sub-pixel 13A is adjacent to and aligned with the first side 1111 of the first sub-pixel 11, that is, their lengths are equal. The first side 1311 of the third sub-pixel 13B is adjacent to and aligned with the second side 1112 of the first sub-pixel 11, that is, their lengths are equal. The first side 1311 of the third sub-pixel 13 may be the short side, and the second side 1312 may be the long side. The sizes of the two third sub-pixels 13 may be different, that is, the lengths of the first side 1311 of the third sub-pixel 13A and the first side 1311 of the third sub-pixel 13B may be different. In this case, the lengths of the first side 1111 and the second side 1112 of the first sub-pixel 11 are different. The lengths of the second side 1312 of the third sub-pixel 13A and the second side 1312 of the third sub-pixel 13B may different. In this case, the lengths of the adjacent sides of the second sub-pixel 12 are different.

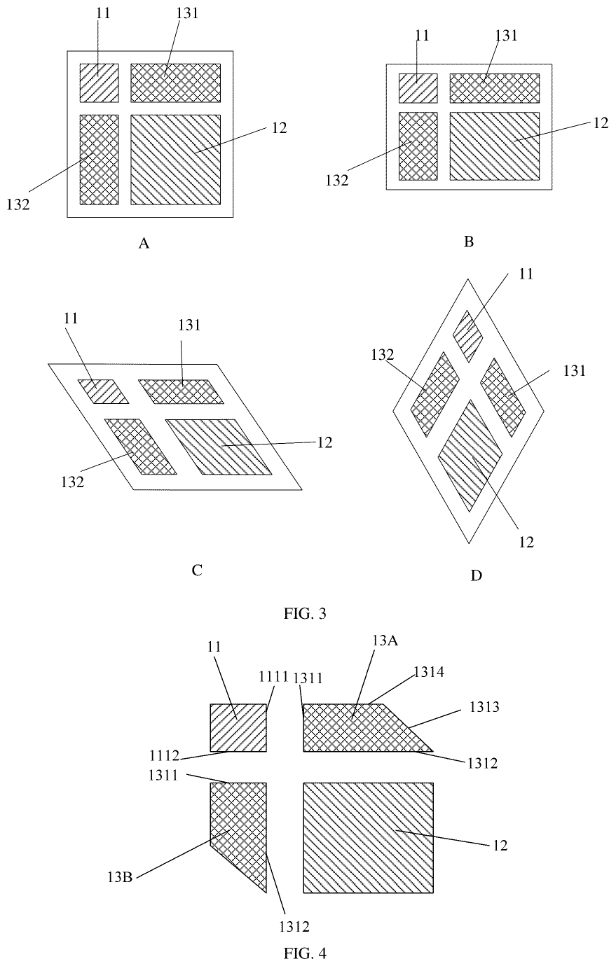

The quadrilateral pixel unit 10 may be in a shape of a square, a rectangle, a parallelogram, or a diamond. At least the first sub-pixel 11 and the second sub-pixel 12 have the same shape as the pixel unit 10. Please refer to FIG. 3, FIG. 3 is a structural schematic view of a second embodiment of a pixel unit according to the present disclosure. As shown in a part A of FIG. 3, when the pixel unit 10 is in a shape of a square, the first sub-pixel 11 and the second sub-pixel 12 are in shapes of squares, and the two third sub-pixels 13 are in shapes of rectangles of the same size and shape. When the pixel unit 10 is in a shape of a rectangle, as shown in a part B of FIG. 3, the first sub-pixel 11, the second sub-pixel 12, and the third sub-pixels 13 are all in shapes of rectangles, the two third sub-pixels 13 are in shapes of rectangles of different sizes. When the pixel unit 10 is in a shape of a parallelogram, as shown in a part C of FIG. 3, the first sub-pixel 11, the second sub-pixel 12, and the two third sub-pixels 13 are all in shapes of parallelograms. When the pixel unit 10 is in a shape of a diamond, as shown in a part D of FIG. 3, the first sub-pixel 11 and the second sub-pixel 12 are in shapes of diamonds, and the third sub-pixels 13 are in shapes of parallelograms.

In some embodiments, the first sub-pixel 11 and the second sub-pixel 12 may be in shapes of squares or diamonds with equal side lengths, and the two third sub-pixels 13 may be of the same size and shape.

In some embodiments, the third sub-pixel 13 may include a third side 1313 (i.e., the opposite side) arranged opposite to the first side 1311 and a fourth side 1314 arranged opposite to the second side 1312. In some embodiments, the length of the third side 1313 may be equal to the length of the first side 1311, and the length of the fourth side 1314 may be equal to the length of the second side 1312, as shown in FIG. 2.

In other embodiments, the length of the third side 1313 may different from the length of the first side 1311, and the length of the fourth side 1314 may different from the length of the second side 1312. Please refer to FIG. 4, FIG. 4 is a structural schematic view of a third embodiment of a pixel unit according to the present disclosure. As shown in FIG. 4, the shape of the pixel unit 10 is not a regular quadrilateral, such as a hexagon. Such a structure of the pixel unit 10 is apparently not conducive to regular arrangement.

The third sub-pixel 13 may be one of a red sub-pixel, a blue sub-pixel, and a green sub-pixel. The first sub-pixel 11 and the second sub-pixel 12 may respectively be the other two of the red sub-pixel, the blue sub-pixel, and the green sub-pixel. Due to differences in display of color, the sizes (areas) of the first sub-pixel 11 and the second sub-pixel 12 are designed differently. Because the first sub-pixel 11 and the second sub-pixel 12 are of different sizes, the first sub-pixel 11, the second sub-pixel 12, and the third sub-pixel 13 in a regular horizontal or vertical arrangement may result in displaying colored edge.

The technical effects of this embodiment are as follows. By splitting one (i.e., the third sub-pixel 13) of a red sub-pixel, a blue sub-pixel, and a green sub-pixel into two sub-pixels and aligning the split sub-pixels with the other two sub-pixels of different colors, the regular arrangement is achieved and the problem that the colored edge is display is reduced.

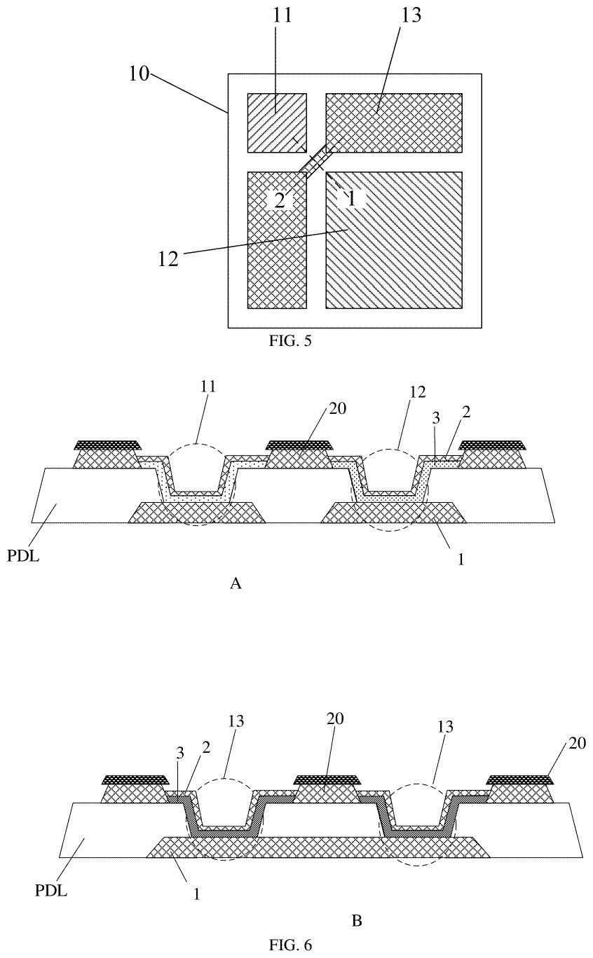

In some embodiments, pixel anodes 1 of two third sub-pixels 13 in the same pixel unit 10 may be connected to each other, that is, the pixel anodes 1 of two third sub-pixels 13 in the same pixel unit 10 may be controlled by the same control signal. Please refer to FIG. 5, FIG. 5 is a structural schematic view of a fourth embodiment of a pixel unit according to the present disclosure. As shown in FIG. 5, the pixel anodes 1 of the two third sub-pixels in the same pixel unit 10 may be connected to each other.

Please refer to FIG. 6, FIG. 6 is a cross-sectional structural schematic view of a first embodiment of the pixel arrangement structure according to the present disclosure. As shown in FIG. 6, adjacent two third sub-pixels 13 share a conductor barrier structure 20 arranged between the first sub-pixel 11 and the second sub-pixel 12. In some embodiments, a part A of FIG. 6 illustrates the cross-sectional structure along the broken line 1 in FIG. 5, and a part B of FIG. 6 illustrates the cross-sectional structure along the broken line 2 in FIG. 5. The part A of FIG. 6 illustrates the conductor barrier structure 20 arranged between the first sub-pixel 11 and the second sub-pixel 12. The part B of FIG. 6 illustrates the conductor barrier structure 20 arranged between adjacent two third sub-pixels 13, which is the conductor barrier structure 20 arranged between the first sub-pixel 11 and the second sub-pixel 12. In this embodiment, the light-emitting regions of adjacent two third sub-pixels 13 are separated by the conductor barrier structure 20, that is, the light-emitting regions of adjacent two third sub-pixels 13 are not connected to each other.

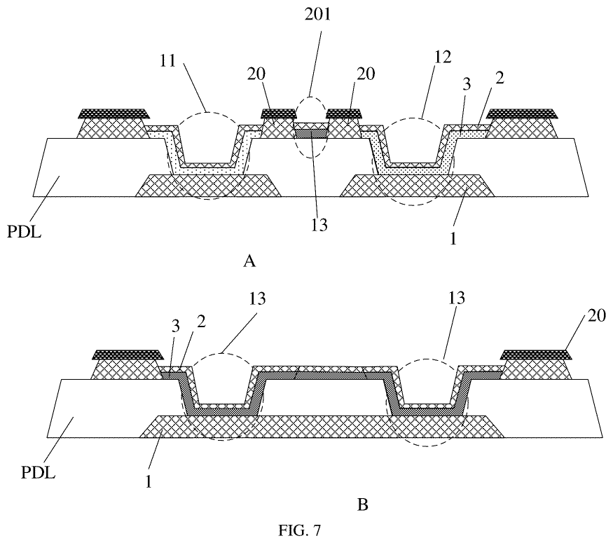

Please refer to FIG. 7, FIG. 7 is a cross-sectional structural schematic view of a second embodiment of a pixel arrangement structure according to the present disclosure. As shown in FIG. 7, a part A of FIG. 7 illustrates the cross-sectional structure along the broken 1 in FIG. 5, and a part B of FIG. 7 illustrates the cross-sectional structure along the broken line 2 in FIG. 5. The total width of the conductor barrier structure 20 arranged between the first sub-pixel 11 and the second sub-pixel 12 may be shorter than the distance between the first sub-pixel 11 and the second sub-pixel 12. As shown in the part A of FIG. 7, the conductor barrier structure 20 arranged between the first sub-pixel 11 and the second sub-pixel 12 may be disconnected at the position close to the center (i.e., the position located between the first sub-pixel 11 and the second sub-pixel 12) to form a bridging channel 201. At least the luminescent layer 3 and pixel cathode 2 of the third sub-pixel 13 may be formed in the bridging channel 201. As shown in the part B of FIG. 7, the luminescent layer 3 and pixel cathode 2 of the third sub-pixel 13 may be formed in the bridging channel 201, such that the luminescent layers 3 of adjacent two third sub-pixels 13 are connected to each other and the pixel cathodes 2 of adjacent two third sub-pixels 13 are connected to each other. In some embodiments, the organic luminescent layers 3 and pixel cathodes 2 of adjacent two third sub-pixels 13 may be arranged on an upper surface of a pixel definition layer (PDL), and the pixel anodes 1 of adjacent two third sub-pixels 13 are connected to each other on the bottom of the PDL. In other embodiments, the pixel anodes 1 of the two third sub-pixels 13 in the same pixel unit 10 may not be connected to each other, which is not limited here.

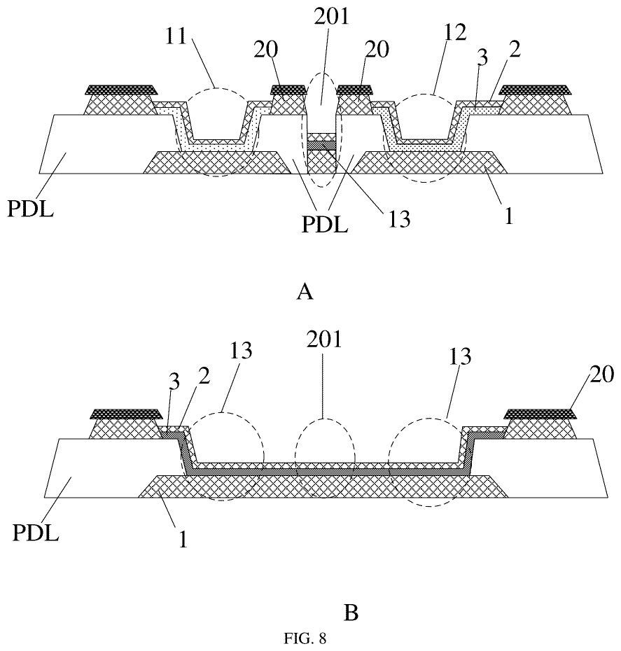

Please refer to FIG. 8, FIG. 8 is a cross-sectional structural schematic view of a third embodiment of a pixel arrangement structure according to the present disclosure. A part A of FIG. 8 illustrates the cross-sectional structure along the broken line 1 in FIG. 5, and a part B of FIG. 8 illustrates the cross-sectional structure along the broken line 2 in FIG. 5. As shown in the part A of FIG. 8, the PDL between the first sub-pixel 11 and the second sub-pixel 12 is disconnected at the bridging channel 201, and the third sub-pixel 13 (including the pixel anode 1, the luminescent layer 3, and the pixel cathode 2) may be arranged in the bridging channel 201. Please refer to the part B of FIG. 8, the PDL arranged between adjacent two third sub-pixels 13 and at the bridging channel 201 is removed, such that the light-emitting regions of adjacent two third sub-pixels 13 are connected to each other. That is, the pixel anodes 1 of adjacent two third sub-pixels 13 are connected to each other, the luminescent layers 3 of adjacent two third sub-pixels 13 are connected to each other, the pixel cathodes 2 of adjacent two third sub-pixels 13 are connected to each other, and the pixel anodes 1 and the luminescent layers 3 are not separated by the PDL, so as to emit light. In the structure shown in FIG. 7, since the pixel anode 1 is not directly connected to the luminescent layer 3 and does not directly power the luminescent layer 3, the light-emitting efficiency of the luminescent layer 3 in the bridging channel 201 is lower than the light-emitting efficiency of the structure shown in FIG. 8.

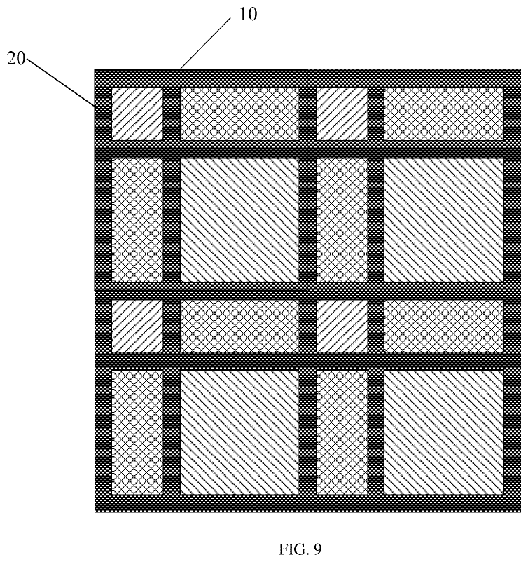

Some embodiments of the present disclosure provide a display panel. Please refer to FIG. 9, FIG. 9 is a structural schematic view of a first embodiment of a display panel according to the present disclosure. As shown in FIG. 9, the display panel may include the pixel arrangement structure described in any of the above embodiments. In some embodiments, the multiple pixel units 10 described in any of the above embodiments are arranged to form the pixel arrangement structure.

Sub-pixels of different colors are separated by the conductor barrier structures 20.

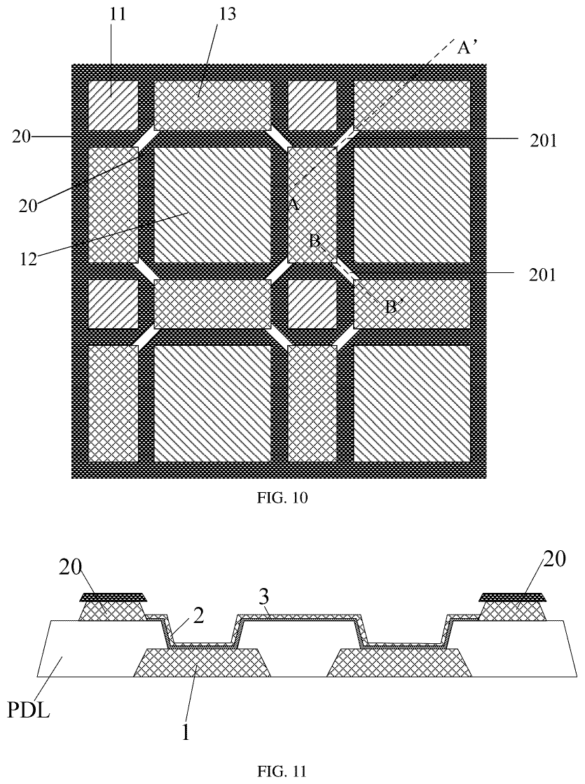

In some embodiments, at least two sub-pixels of the same color may share a part of the conductor barrier structure 20. In some embodiments, please refer to FIG. 10, FIG. 10 is a structural schematic view of a second embodiment of a display panel according to the present disclosure. As shown in FIG. 10, the conductor barrier structure 20 between the two third sub-pixels 13 in the same pixel unit 10 may be removed, and the two third sub-pixels 13 in the same pixel unit 10 may share the conductor barrier structure 20 between the first sub-pixel 11 and the second sub-pixel 12, thereby improving the aperture ratio of the third sub-pixels 13. In the entire display panel, all adjacent third sub-pixels 13 may share the conductor barrier structure 20 between the first sub-pixel 11 and the second sub-pixel 12. A part of the conductor barrier structure 20 between the first sub-pixel 11 and the second sub-pixel 12 is disconnected to form a bridging channel, the luminescent layers 3 of adjacent two third sub-pixels 13 may be at least connected to each other, and pixel cathodes 2 of adjacent two third sub-pixels 13 may be at least connected to each other. In some embodiments, the pixel anodes 1 of the two third sub-pixels 13 in the same pixel unit 10 may be connected each other at the bridging channel, thereby improving the aperture ratio of the third sub-pixels.

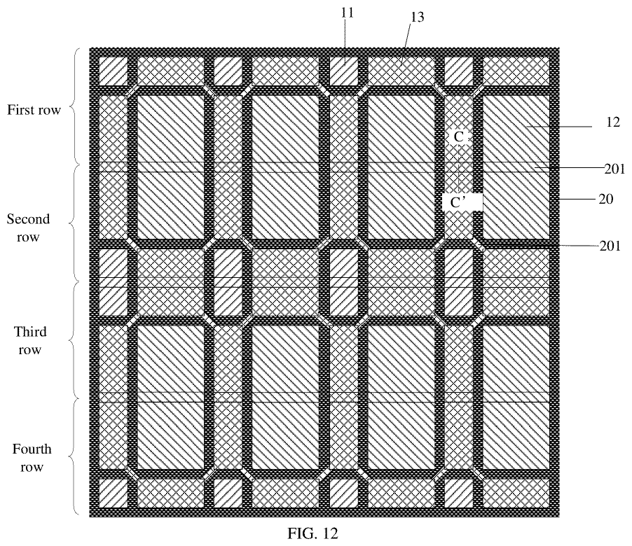

Please refer to FIG. 11, FIG. 11 is a cross-sectional structural schematic view of a first specific embodiment of a display panel according to the present disclosure, and illustrates the cross-sectional structure along the broken line B-B′ in FIG. 10. Each sub-pixel may include a pixel anode 1, a pixel cathode 2, and a luminescent layer 3 between the pixel anode 1 and the pixel cathode 2. FIG. 11 illustrates the cross-sectional schematic view of a structure located between adjacent two third sub-pixels 11 in different pixel units 10. As shown in FIG. 11, the pixel anodes 1 of adjacent two third sub-pixels 13 in different pixel units 10 may be disconnected, and the luminescent layers 3 of adjacent two third sub-pixels 13 in different pixel units 10 may be connected to each other on the surface of the PDL, and pixel cathodes 2 of adjacent two third sub-pixels 13 in different pixel units 10 are connected to each other on the surface of the PDL.

In this embodiment, adjacent two sub-pixels may be separated by the PDL. In a process without FMM, adjacent two sub-pixels may be separated by the conductor barrier structure 20, and the he conductor barrier structure 20 may include a conductive layer and an eave layer. The conductor barrier structure 20 may be arranged on the PDL to separate the luminescent layers of each sub-pixel during the evaporation deposition process. The conductive part of the conductor barrier structure 20 may be electrically connected to the pixel cathode 2 of each sub-pixel, so that all pixel cathodes 2 on the display panel are connected to each other to form an entire surface cathode. In this embodiment, adjacent two sub-pixels of the same color (third sub-pixels) share the conductor barrier structures 20 on their both sides. A part of the conductor barrier structure 20 between the two sub-pixels may be removed to further improve the aperture ratio of the sub-pixels of the same color. The pixel anodes 1 of the two sub-pixels of the same color in the same pixel unit may be shared (i.e., connected to each other) or not shared. Sub-pixels of the same color in different pixel units may share a part of the conductor barrier structure 20, that is, a part of the conductor barrier structure 20 between the sub-pixels of the same color in different pixel units may be removed, and the conductor barrier structure 20 at the edge of the display panel may be shared. In this way, sub-pixels of the same color in the entire panel (i.e., the entire display panel) share the conductor barrier structure 20, thereby improving the aperture ratio of the sub-pixels (such as the third sub-pixels) of the same color in the entire display panel.

In the above embodiments, the pixel units in the pixel arrangement structure are arranged in an array.

Some embodiments of the present disclosure provide a second pixel arrangement structure. Please refer to FIG. 12, FIG. 12 is a structural schematic view of a third embodiment of a display panel according to the present disclosure. As shown in FIG. 12, adjacent two rows of pixel units 10 may be symmetrically arranged. In other embodiments, adjacent two columns of pixel units 10 may be symmetrically arranged, and have an arrangement structure similar to FIG. 12, which is not repeated here. The pixel units 10 in even-numbered rows may be flipped to be symmetrical with the pixel units 10 in odd-numbered rows. One third sub-pixel 13 and one second sub-pixel 12 of the pixel unit 10 in the first row may be adjacent to one third sub-pixel 13 and one second sub-pixel 12 of pixel unit 10 in the second row. One third sub-pixel 13 and one first sub-pixel 11 of pixel unit 10 in the second row may be adjacent to one third sub-pixel 13 and one first sub-pixel 11 of pixel unit 10 in the third row.

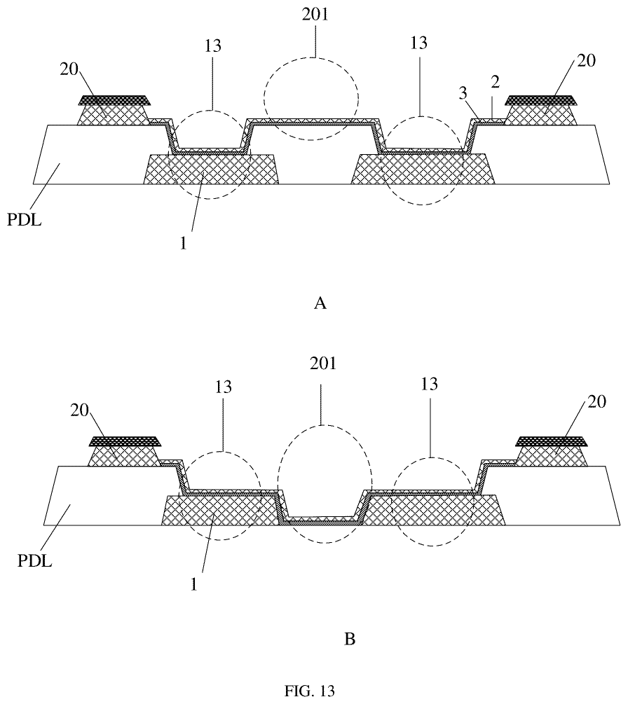

In this embodiment, adjacent first sub-pixels 11 may share the conductor barrier structure 20, and/or adjacent second sub-pixels 12 may share the conductor barrier structure 20, and/or adjacent third sub-pixels 13 may share the conductor barrier structure 20. The conductor barrier structure 20 may surround adjacent two first sub-pixels 11, adjacent two second sub-pixels 12, and adjacent two third sub-pixels 13. The bridging channel 201 may be arranged between adjacent two first sub-pixels 11, the bridging channel 201 may be arranged between adjacent two second sub-pixels 12, and the bridging channel 201 may be arranged between adjacent two third sub-pixels 13. Adjacent two first sub-pixels 11 may be connected to each other through the bridging channel 201, adjacent two second sub-pixels 12 may be connected to each other through the bridging channel 201, and adjacent two third sub-pixels 13 may be connected to each other through the bridging channel 201. At least the luminescent layer 3 and pixel cathodes 2 of the first sub-pixel 11 may be arranged in the bridging channel 201 and between adjacent two first sub-pixels 11. At least the luminescent layer 3 and pixel cathode 2 of the second sub-pixel 12 may be arranged in the bridging channel 201 and between adjacent two second sub-pixels 12. At least the luminescent layer 3 and pixel cathode 2 of the third sub-pixel 13 may be arranged in the bridging channel 201 and between adjacent two third sub-pixels 13. The pixel anodes 1 arranged in the bridging channels 201 and between adjacent first sub-pixels 11 in upper and lower rows may be spaced apart, the pixel anodes 1 arranged in the bridging channels 201 and between adjacent second sub-pixels 12 in upper and lower rows may be spaced apart, and the pixel anodes 1 arranged in the bridging channels 201 and between adjacent third sub-pixels 13 in upper and lower rows may be spaced apart. In some embodiments, please refer to FIG. 13, FIG. 13 is a cross-sectional structural schematic view of a second specific embodiment of a display panel according to the present disclosure. For example, FIG. 13 is the cross-sectional structure along the broken line C-C′ in FIG. 12, and illustrates the structure of the bridging channel between adjacent third sub-pixels 13 in upper and lower rows. The cross-sectional structure between adjacent first sub-pixels 11 arranged symmetrically in upper and lower rows is similar to the cross-sectional structure in FIG. 13, and the cross-sectional structure between adjacent second sub-pixels 12 arranged symmetrically in upper and lower rows is similar to the cross-sectional structure in FIG. 13. As shown in FIG. 13, adjacent third sub-pixels 13 in upper and lower rows may be third sub-pixels in different pixel units 10, and their pixel anodes may be disconnected. In some embodiments, a PDL may be arranged between adjacent two third sub-pixels 13, and the conductor barrier structure on the surface of the PDL may be removed, so that the luminescent layers 3 of adjacent two third sub-pixels 13 are connected to each other on the surface of the PDL and the pixel cathodes 2 of adjacent two third sub-pixels 13 are connected to each other on the surface of the PDL, as shown in a part A of FIG. 13. In other embodiments, the PDL located between adjacent two third sub-pixels 13 may be removed, and the pixel anodes 1 of adjacent two third sub-pixels 13 may be spaced apart. The luminescent layers 3 of adjacent two third sub-pixels 13 may be connected each other on the substrate, and the pixel cathodes 2 of adjacent two third sub-pixels 13 may be connected each other on the substrate, as shown in a part B of FIG. 13.

In this embodiment, the pixel anodes of the two third sub-pixels 13 in the same pixel unit 10 may be connected to each other in a diagonal direction, the luminescent layers 3 of the two third sub-pixels 13 in the same pixel unit 10 may be connected to each other in a diagonal direction, and the pixel cathodes 2 of the two third sub-pixels 13 in the same pixel unit 10 may be connected to each other in a diagonal direction. The cross-sectional structure between the two third sub-pixels 13 in the same pixel unit 10 may be referred to in the part B of FIGS. 6-8, which are not repeated here.

The technical effects of the present disclosure are as follows. By splitting one of the red, blue, and green sub-pixels into two sub-pixels and aligning the split sub-pixels with the other two sub-pixels of different colors and sizes, thereby meeting the regular arrangement and reducing the problem that the colored edge is displayed. Furthermore, by forming the bridging channel between sub-pixels of the same color, the luminescent layers of adjacent two sub-pixels of the same color may be connected to each other, and the pixel cathodes of adjacent two sub-pixels of the same color may be connected to each other, thereby increasing the light-emitting area of the light-emitting region, fully utilizing the conductor barrier structures between adjacent two sub-pixels, and improving the aperture ratio of the sub-pixels.

The above are only some embodiments of the present disclosure, and do not limit the scope of the present disclosure. Any equivalent structural or process transformations made using the content of the specification and drawings of the present disclosure, or direct or indirect applications in other related technical fields, fall within the scope of the present disclosure.

1. A pixel arrangement structure, comprising:
a plurality of pixel units;
wherein each of the pixel plurality of pixel units comprises a first sub-pixel and a second sub-pixel of different sizes, and two third sub-pixels aligned with the first sub-pixel and the second sub-pixel, respectively;
in each of the pixel plurality of pixel units, the first sub-pixel and the second sub-pixel are diagonally arranged, one of the two third sub-pixels is aligned with the first sub-pixel in a first direction and aligned with the second sub-pixel in a second direction, another of the two third sub-pixels is aligned with the second sub-pixel in the first direction and aligned with the first sub-pixel in the second direction, and the first direction and the second direction are arranged at an angle.

2. The pixel arrangement structure according to claim 1, wherein each of the first direction and the second direction are arranged at 90 degrees.

3. The pixel arrangement structure according to claim 2, wherein each of the first sub-pixel and the second sub-pixel is in a shape of a square or a diamond with four sides of equal length.

4. The pixel arrangement structure according to claim 3, wherein in each of the pixel plurality of pixel units, each of the two third sub-pixels at least comprises one first side and one second side that are arranged adjacent to each other and have different lengths, the two first sides of the two third sub-pixels are adjacent to and aligned with the first sub-pixel, and the two second sides of the two third sub-pixels are adjacent to and aligned with the second sub-pixel.

5. The pixel arrangement structure according to claim 4, wherein in each of the pixel plurality of pixel units, each of the two third sub-pixel further comprises one third side opposite to the first side and one fourth side opposite to the second side; a length of the third side is the same as a length of the first side, a length of the fourth side is the same as a length of the second side, and each of the plurality of pixel units is in a shape of a square of a diamond with four sides of equal length.

6. The pixel arrangement structure according to claim 1, wherein pixel anodes of the two third sub-pixels in each of the plurality of pixel units are connected to each other.

7. The pixel arrangement structure according to claim 1, wherein in each of the pixel plurality of pixel units, at least a part of a conductor barrier structure arranged between two third sub-pixels is removed.

8. The pixel arrangement structure according to claim 7, wherein in each of the pixel plurality of pixel units, a width of the conductor barrier structure between the first sub-pixel and the second sub-pixel is smaller than a distance between the first sub-pixel and the second sub-pixel to provide a bridging channel, and the two third sub-pixels are connected to each other through the bridging channel; the bridging channel is spaced apart from the first sub-pixel and the second sub-pixel, and a pixel definition layer between the first sub-pixel and the second sub-pixel is disconnected at the bridging channel.

9. The pixel arrangement structure according to claim 8, wherein adjacent two rows or two columns of pixel units of the plurality of pixel units are symmetrically arranged;
the first sub-pixels of the adjacent two rows or two columns of pixel units are arranged adjacent to each other, and/or the second sub-pixels of the adjacent two rows or two columns of pixel units are arranged adjacent to each other, and/or the third sub-pixels of the adjacent two rows or two columns of pixel units are arranged adjacent to each other;
a bridging channel is arranged between the adjacent first sub-pixels, and/or a bridging channel is arranged between the adjacent second sub-pixels, and/or a bridging channel is arranged between the adjacent third sub-pixels.

10. A display panel, comprising:
a plurality of pixel units;
wherein each of the pixel plurality of pixel units comprises a first sub-pixel and a second sub-pixel of different sizes, and two third sub-pixels aligned with the first sub-pixel and the second sub-pixel, respectively;
in each of the pixel plurality of pixel units, the first sub-pixel and the second sub-pixel are diagonally arranged, one of the two third sub-pixels is aligned with the first sub-pixel in a first direction and aligned with the second sub-pixel in a second direction, another of the two third sub-pixels is aligned with the second sub-pixel in the first direction and aligned with the first sub-pixel in the second direction, and the first direction and the second direction are arranged at an angle;
wherein sub-pixels of different colors are separated by a conductor barrier structure, and at least two sub-pixels of a same color share a part of the conductor barrier structure.

11. The display panel according to claim 10, wherein the first direction and the second direction are arranged at 90 degrees.

12. The display panel according to claim 11, wherein each of the first sub-pixel and the second sub-pixel is in a shape of a square or a diamond with four sides of equal length.

13. The display panel according to claim 12, wherein in each of the pixel plurality of pixel units, each of the two third sub-pixels at least comprises one first side and one second side that are arranged adjacent to each other and have different lengths, the two first sides of the two third sub-pixels are adjacent to and aligned with the first sub-pixel, and the two second sides of the two third sub-pixels are adjacent to and aligned with the second sub-pixel.

14. The display panel according to claim 13, wherein in each of the pixel plurality of pixel units, each of the two third sub-pixel further comprises one third side opposite to the first side and one fourth side opposite to the second side; a length of the third side is the same as a length of the first side, a length of the fourth side is the same as a length of the second side, and each of the plurality of pixel units is in a shape of a square of a diamond with four sides of equal length.

15. The display panel according to claim 10, wherein pixel anodes of the two third sub-pixels in each of the plurality of pixel units are connected to each other.

16. The display panel according to claim 10, wherein in each of the pixel plurality of pixel units, at least a part of a conductor barrier structure arranged between the two third sub-pixels is removed.

17. The display panel according to claim 16, wherein in each of the pixel plurality of pixel units, a width of the conductor barrier structure between the first sub-pixel and the second sub-pixel is smaller than a distance between the first sub-pixel and the second sub-pixel to provide a bridging channel, and the two third sub-pixels are connected to each other through the bridging channel; the bridging channel is spaced apart from the first sub-pixel and the second sub-pixel, and a pixel definition layer between the first sub-pixel and the second sub-pixel is disconnected at the bridging channel.

18. The display panel according to claim 17, wherein adjacent two rows or two columns of pixel units of the plurality of pixel units are symmetrically arranged;
the first sub-pixels of the adjacent two rows or two columns of pixel units are arranged adjacent to each other, and/or the second sub-pixels of the adjacent two rows or two columns of pixel units are arranged adjacent to each other, and/or the third sub-pixels of the adjacent two rows or two columns of pixel units are arranged adjacent to each other;
a bridging channel is arranged between the adjacent first sub-pixels, and/or a bridging channel is arranged between the adjacent second sub-pixels, and/or a bridging channel is arranged between the adjacent third sub-pixels.

19. The display panel according to claim 10, wherein at least a part of a conductor barrier structure arranged between any two adjacent third sub-pixels of different pixel units is removed.

20. A display panel, comprising:
a plurality of pixel units;
wherein each of the pixel plurality of pixel units comprises a first sub-pixel and a second sub-pixel of different sizes and two third sub-pixels aligned with the first sub-pixel and the second sub-pixel;
in each of the pixel plurality of pixel units, the first sub-pixel and the second sub-pixel are diagonally arranged;
each of the pixel plurality of pixel units is in a shape of a parallelogram.
